(19) United States
(12) Patent Application Publication
(10) Pub. No.: US 2011/0221362 A1
(43) Pub. Date: Sep. 15, 2011

(54) ELECTRONIC DEVICE

(75) Inventors: XIANG CAO, Shenzhen (CN); ZHEN-XING YE, Shenzhen (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/848,325

(22) Filed: Aug. 2, 2010

(30) Foreign Application Priority Data
Mar. 12, 2010 (CN) 201010123242.1

(51) Int. Cl. H05B 37/02; G02B 6/00; H01L 33/02

(52) U.S. Cl. 315/362; 362/551; 362/555

(57) ABSTRACT

An electronic device includes a housing, a circuit board received in the housing, and an indicator module. The indication module includes an illumination member electrically connected to the circuit board, and an optical fiber segment coupled to the illumination member for transmitting light generated by the illumination member. The optical fiber segment includes a light input end facing the illumination member to receive light, and a light output end connected to the housing to output light.

### BACKGROUND

1. Technical Field

The present disclosure generally relates to an electronic device.

2. Description of Related Art

A typical electronic device, such as a desktop computer, or a server computer, is provided with a detection module to detect the working state of the hardware and the software, and an indicator module electrically connected to the detection module for showing the detected working state to users. A commonly used indicator module includes a signal terminal electrically connected to the detection module, a light-emitting diode (LED) assembly mounted in the housing of the electronic device, and an electrical wiring connecting the signal terminal and the LED assembly. The LED assembly includes a LED and a circuit board on which the LED is mounted. However, because of the requirement of the electrical wiring for operation, many problems have been encountered. For example, the electromagnetic interference that can create problems with other components is thereby added. In addition, when the indicator module fails to work, it is relatively difficult to maintain, thus the electrical wiring needs to be treated carefully.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a first embodiment of an electronic device, the electronic device includes an indicator.

FIG. 2 is a cross sectional view of the electronic device of FIG. 1, taken along the line II-II.

FIG. 3 is a cross sectional view of a second embodiment of an electronic device.

FIG. 4 is a cross sectional view of a third embodiment of an electronic device.

### DETAILED DESCRIPTION

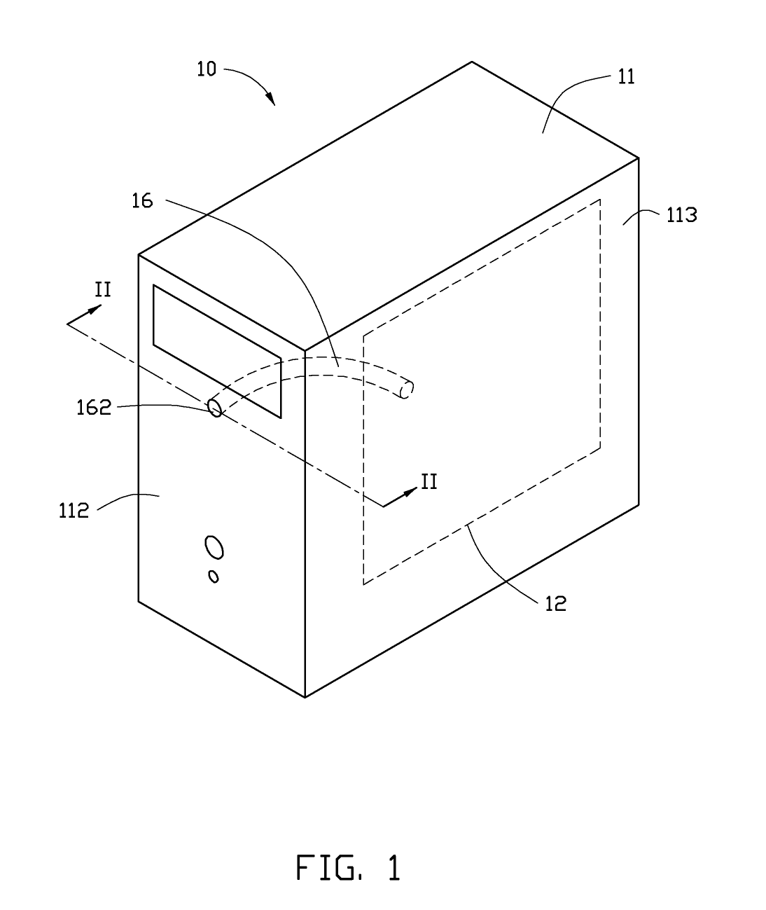

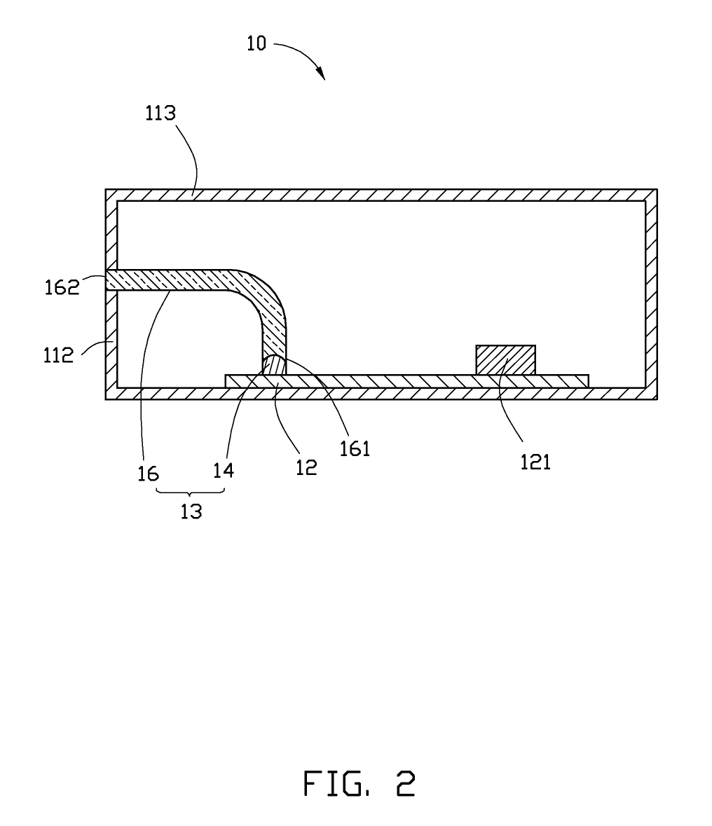

Referring to FIGS. 1 and 2, a first embodiment of an electronic device 10 is a desktop computer. The electronic device 10 includes a housing 11, a circuit board 12 received in the housing 11, and an indicator module 13. Other components, such as a hard disk, a memory bank, and a center process unit (CPU), are not shown in the drawings. The indicator module 13 includes an illumination member 14 electrically connected to the circuit board 12, and an optical fiber segment 16 for transmitting light from one end to another end. The housing 11 includes a main frame 112 and a rear panel 113 connected to a rear side of the main frame 112. The illumination member 14 may be a light emitting diode (LED), or other electric lighting fixture. In the first embodiment, the illumination member 14 is a LED which is surfaced mounted.

The optical fiber segment 16 includes a light input end 161 and a light output end 162. The light input end 161 faces the illumination member 14 to receive the light generated by the illumination member 14. The light output end 162 is connected to the rear panel 113 of the housing 11 to output the light. Therefore, the light output end 162 is capable of outputting light generated by the illumination member 14, thus facilitating the monitoring of working state.

The circuit board 12 includes a control unit 121 electrically connected to the illumination member 14. The control unit 121 is used to detect a plurality of system errors of the electronic device 10 and to determine the on-off control of the illumination member 14 in response to the detected system errors. For example, when the control unit 121 detects a system error, the control unit 121 activates the illumination member 14, and the light generated by the illumination member 14 emits from the light output end 162 of the optical fiber segment 16. Otherwise, the illumination member 14 is off. Therefore, users can monitor the working state of the computer system via the indicator module 13. The control unit 121 can be configured to detect the working state for other components of the electronic device 10, such as the temperature of the CPU, or the working condition of the hard disk.

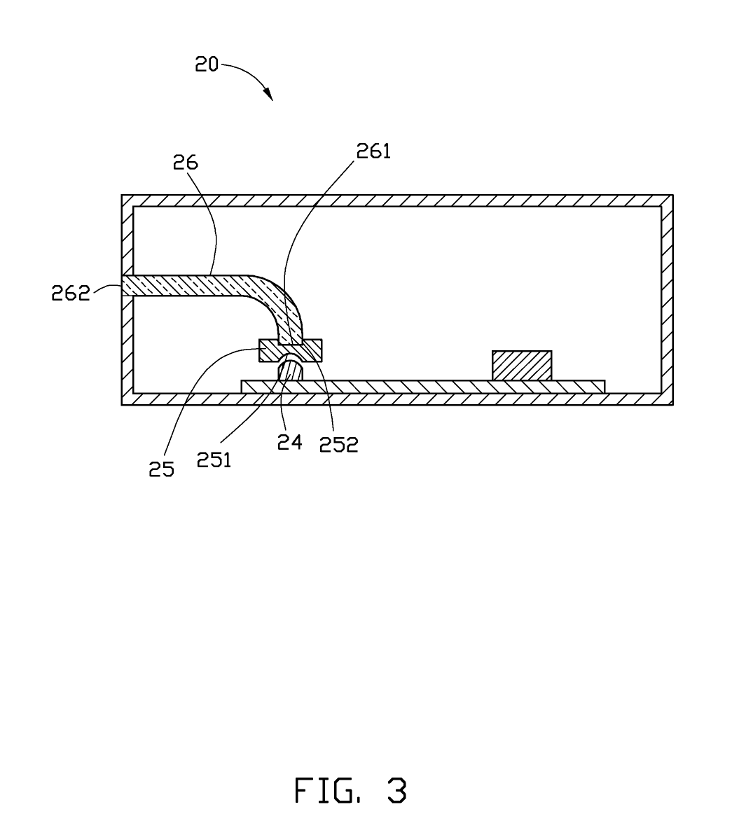

Referring to FIG. 3, a second embodiment of the electronic device 20 is shown. The second embodiment differs from the first embodiment only in that the electronic device 20 further includes a light guiding post 25 located between the illumination member 24 and the light input end 261 of the optical fiber segment 26. The light guiding post 25 is capable of focusing the light generated by the illumination member 24, thus making the light outputting from the light output end 162 brighter.

The light guiding post 25 defines a receiving groove 251 in the first end thereof, and a connection groove 252 in the second end thereof. The illumination member 24 is at least partially received in the receiving groove 251. The light input end 261 is received in the connection groove 252. The receiving groove 251 has an inner surface (not labeled) which has a shape that can focus the light from the illumination member 24, such as a substantially arcuate surface, or a conic surface.

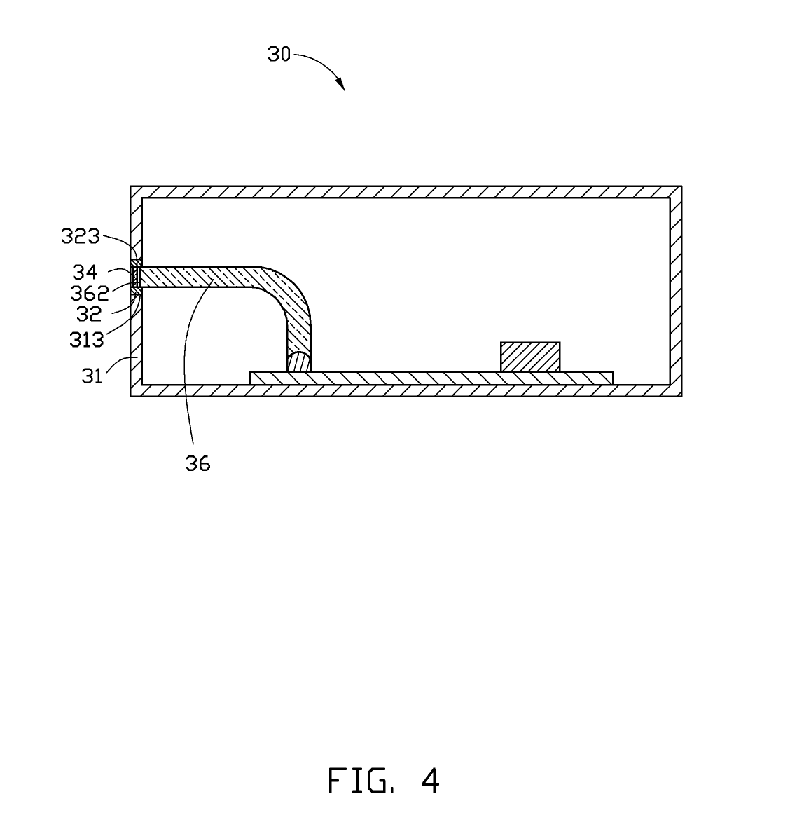

Referring to FIG. 4, a third embodiment of the electronic device 30 is shown. The third embodiment differs from the first embodiment only in that the electronic device 30 further includes an assembly base 32 connected to the light output end 362 of the optical fiber segment 36, and a lens 34 for focusing or distributing the light outputted from the light output end 362 according to a plurality of specific applications. The housing 31 defines an assembly hole 313 for receiving the assembly base 32. The assembly base 32 defines a receiving hole 323 for receiving the lens 34.

It should also be understood that the electronic device 10, 20, 30 described is not limited to a desktop computer, and can alternatively be a server computer or the like.

It is believed that the present embodiments and their advantages will be understood from the foregoing description, and it will be apparent that various changes may be made thereto without departing from the spirit and scope of the disclosure or sacrificing all of its material advantages.

1. An electronic device comprising:
a housing;
a circuit board received in the housing; and
an indicator module comprising:
an illumination member electrically connected to the circuit board; and
an optical fiber segment coupled to the illumination member for transmitting light generated by the illumination member, wherein the optical fiber segment comprises a light input end facing the illumination member to receive light and a light output end connected to the housing to output light.

2. The electronic device of claim 1, wherein the circuit board comprises a control unit electrically connected to the illumination member to determine the on-off control of the illumination member.

3. The electronic device of claim 1, wherein the illumination member is a light-emitting diode (LED).

4. The electronic device of claim 3, wherein the light-emitting diode is surface mounted.

5. The electronic device of claim 1, further comprising a light guiding post located between the illumination member and the light input end.

6. The electronic device of claim 5, wherein the light guiding post defines a receiving groove to at least partially receive the illumination member, and a connection groove opposite to the receiving groove; and the connection groove is connected to the light input end.

7. The electronic device of claim 6, wherein an inner surface of the receiving groove is substantially arcuate.

8. The electronic device of claim 6, wherein an inner surface of the receiving groove is substantially conic.

9. The electronic device of claim 1, further comprising at least one lens located in the housing to receive light outputted from the light output end.

10. The electronic device of claim 9, further comprising an assembly base mounted in the housing to receive the at least one lens.

11. The electronic device of claim 10, wherein the housing defines an assembly hole to receive the assembly base, and the assembly base defines a receiving hole to receive the at least one lens.

12. An electronic device comprising:
a housing;
a circuit board received in the housing; and
an indicator module comprising:
an illumination member electrically connected to the circuit board; and
an optical fiber segment coupled to the illumination member for transmitting light generated by the illumination member, the optical fiber segment comprising a light input end facing the illumination member to receive light and a light output end connected to the housing to output light;
a control unit electrically connected to the illumination member for determining the on-off control of the illumination member; and
a light guiding post located between the illumination member and the light input end.

13. The electronic device of claim 12, wherein the illumination member is a light-emitting diode (LED).

14. The electronic device of claim 13, wherein the light-emitting diode is surface mounted.

15. The electronic device of claim 12, wherein the light guiding post defines a receiving groove to at least partially receive the illumination member, and a connection groove opposite to the receiving groove; and the connection groove is connected to the light input end.

16. The electronic device of claim 15, wherein an inner surface of the receiving groove is substantially arcuate.

17. The electronic device of claim 15, wherein an inner surface of the receiving groove is substantially conic.

18. The electronic device of claim 12, further comprising at least one lens located in the housing to receive light output from the light output end.

19. The electronic device of claim 18, further comprising an assembly base mounted in the housing to receive the at least one lens.

20. The electronic device of claim 19, wherein the housing defines an assembly hole to receive the assembly base, and the assembly base defines a receiving hole to receive the at least one lens.
